(19) United States
(12) Patent Application Publication
(10) Pub. No.: US 2013/0175693 A1
(43) Pub. Date: Jul. 11, 2013

(54) SEMICONDUCTOR DEVICES

(71) Applicant: SAMSUNG ELECTRONICS CO., LTD., Suwon-si (KR)

(72) Inventors: TAE SOO KIM, SEOUL (KR); JEEYONG KIM, HWASEONG-SI (KR); VIET HA NGUYEN, YONGING-SI (VN); JAIHYUK SONG, SEONGNAM-SI (KR); SANGHOON AHN, GOYANG-SI (KR); GILHEYUN CHOI, SEOUL (KR)

(73) Assignee: SAMSUNG ELECTRONICS CO., LTD., SUWON-SI (KR)

(21) Appl. No.: 13/723,303

(22) Filed: Dec. 21, 2012

(30) Foreign Application Priority Data
Jan. 6, 2012 (KR) 10-2012-0002043

(51) Int. Cl. H01L 23/48

(52) U.S. Cl. CPC H01L 23/481
USPC 257/762; 257/774

(57) ABSTRACT

A semiconductor device includes a substrate, at least one transistor integrated with the substrate, an interlayer insulating layer on the substrate, a conductive line extending within the interlayer insulating layer and electrically connected to the transistor, and at least one capping layer containing carbon in an amount of about 2 to about 7.5 atomic percent. The capping layer may cover the interlayer insulating layer in which the conductive line extends.

### PRIORITY STATEMENT

This U.S. non-provisional patent application claims priority under 35 U.S.C. §119 to Korean Patent Application No. 10-2012-0002043, filed on Jan. 6, 2012, in the Korean Intellectual Property Office, the entire contents of which are hereby incorporated by reference.

### BACKGROUND OF THE INVENTION

The inventive concept relates to semiconductor devices, and more particularly, to interconnection structures of semiconductor devices.

Due to their small size, multifunctionality, and/or low-cost characteristics, semiconductor devices are considered important elements in the electronics industry. Some semiconductor devices include a memory device for storing data, a logic device for processing data, and a hybrid device capable of performing various memory storage and data processing functions simultaneously.

There is a growing demand for electronic products that operate faster and/or are more efficient when it comes to their power consumption. To meet these demands, the semiconductor devices for these products must perform at higher speeds and/or must be operable using low amounts of power. To this end, different ways are being looked at to increase the integration density, that is, the elements per unit area, of a semiconductor device. Features of a semiconductor device that are being scaled down include interconnection structures that connect transistors of the semiconductor device to other components and include conductive lines. However, increasing the integration density of interconnection structures of a semiconductor device may often compromise the reliability of the device.

### SUMMARY

According to an aspect of the inventive concept, there is provided a semiconductor device that includes a substrate and at least one transistor integrated with the substrate, an interlayer insulating layer on the substrate, a conductive line extending within the interlayer insulating layer and electrically connected to the transistor, and a capping layer covering the interlayer insulating layer, and in which the capping layer comprises material containing carbon present in an amount of about 2 to about 7.5 atomic percent.

According to another aspect of the inventive concept, there is provided a semiconductor device that includes a substrate and at least one transistor integrated with the substrate, interlayer insulating layers on the substrate, a conductive line extending within one of the interlayer insulating layers, a plug of conductive material extending through another of the interlayer insulating layers and electrically connected to the conductive line, and a capping layer interposed between said one and said another of the interlayer insulating layers and covering the conductive line, and in which the capping layer comprises material containing carbon present in an amount of about 2 to about 7.5 atomic percent.

### BRIEF DESCRIPTION OF THE DRAWINGS

The inventive concept will be more clearly understood from the following detailed description of preferred embodiments thereof taken in conjunction with the accompanying drawings. In the drawings:

FIG. 1 is a sectional view of a semiconductor device according to the inventive concept;

FIG. 2 is an enlarged view of portion A of the semiconductor device of FIG. 1;

FIG. 3 is a block diagram of an example of a memory system including at least one semiconductor device according to the inventive concept;

FIG. 4 is a block diagram of an example of a memory card including at least one semiconductor device according to the inventive concept; and

FIG. 5 is a block diagram of an example of an information processing system including at least one semiconductor device according to the inventive concept.

### DETAILED DESCRIPTION OF THE PREFERRED EMBODIMENTS

The inventive concept will be described more fully hereinafter with reference to the accompanying drawings. In the drawings, the sizes and relative sizes and shapes of elements and layers shown in section may be exaggerated for clarity. In particular, the cross-sectional illustrations of the semiconductor device are schematic. Also, like numerals are used to designate like elements throughout the drawings.

It will also be understood that when an element or layer is referred to as being “on” or “connected to” another element or layer, it can be directly on or directly connected to the other element or layer or intervening elements or layers may be present. In contrast, when an element or layer is referred to as being “directly on” or “directly connected to” another element or layer, there are no intervening elements or layers present. The same applies to the term “interposed”. Furthermore, in the context of the inventive concept, the term “connected” will most often refer to an electrical connection.

Furthermore, spatially relative terms, such as “upper,” and “lower” are used to describe an element's and/or feature's relationship to another element(s) and/or feature(s) as illustrated in the figures. Thus, the spatially relative terms may apply to orientations in use which differ from the orientation depicted in the figures. Obviously, though, all such spatially relative terms refer to the orientation shown in the drawings for ease of description and are not necessarily limiting as embodiments according to the inventive concept can assume orientations different than those illustrated in the drawings when in use. In addition, the terms “upper”, “top”, “lower” or “bottom” as used to describe a surface generally refer not only to the orientation depicted in the drawings but to the fact that the surface is the uppermost or bottommost surface in the orientation depicted, as would be clear from the drawings and context of the written description.

Other terminology used herein for the purpose of describing particular examples or embodiments of the inventive concept is to be taken in context. For example, the terms “comprises” or “comprising” when used in this specification specifies the presence of stated features but does not preclude the presence or additional features.

The inventive concept will now be described with reference to NAND FLASH memory devices, in which FLASH memory cells constitute a NAND-type cell array, as an example. However, the inventive concept is not limited to NAND FLASH memory devices but is applicable to various other types of semiconductor devices having memory cells. For example, the inventive concept can be realized as a NOR-type FLASH memory device.

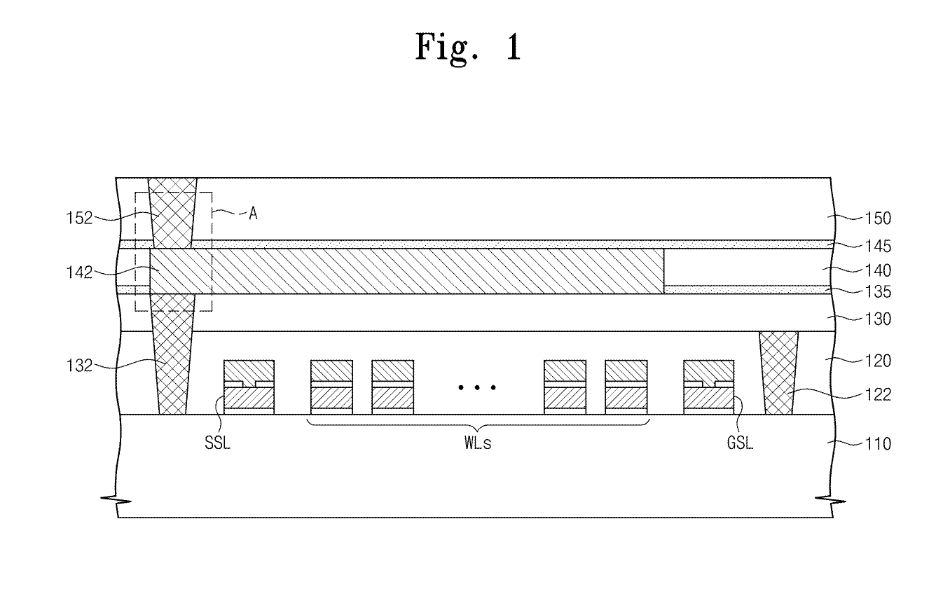

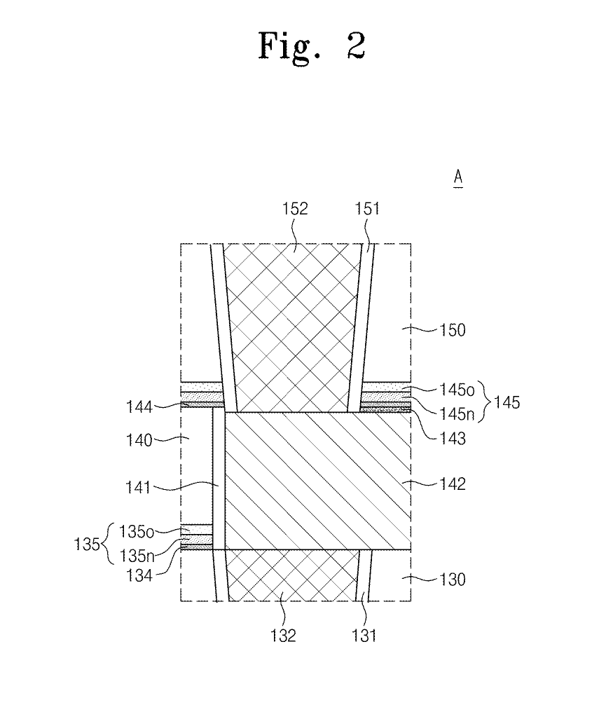

Referring now to FIG. 1 and FIG. 2, a semiconductor device according to the inventive concept includes a substrate 110. The substrate 110 may comprise or consist of a semiconductor material. For example, the substrate 110 may be a silicon (Si) or germanium (Ge) substrate.

A string structure is provided on the substrate 110. The string structure is constituted by a pair of selection transistors GSL and SSL and a plurality of memory transistors WLs interposed therebetween, in this example. Each of the memory transistors WLs may include a data storing element. The data storing element may be an electrically isolated conductor (e.g., a floating gate electrode).

In particular, in the example shown in FIG. 1, each of the memory transistors WLs has a gate structure including a tunnel insulating layer, a floating gate electrode, and an inter-gate insulating layer, which are sequentially stacked between the substrate 110 and a control gate electrode. Alternatively, the memory transistors WLs may have a gate structure including a charge trap layer.

The selection transistors GSL and SSL may have substantially the same stacked structure as the memory transistors WLs, except for the contact between the control and floating gate electrodes. Also, each of the selection transistors GSL and SSL may have a width greater than that of each of the memory transistors WLs.

A first interlayer insulating layer 120 and a second interlayer insulating layer 130 cover the string structure on the substrate 110. At least one of the first and second interlayer insulating layers 120 and 130 may include at least one of silicon oxide and (porous or non-porous) silicon carbon oxide. According to one aspect of the inventive concept, at least one of the first and second interlayer insulating layers 120 and 130 is formed of material having low permittivity. For example, the first and second interlayer insulating layers 120 and 130 may each be a TetraEthly OrthoSilicate (TEOS) oxide layer.

A common source line contact plug 122 and a bit line contact plug 132 may be provided at opposite sides of the string structure, respectively. The contact plugs 122 and 132 extend through the first interlayer insulating layer 120 or the first and second interlayer insulating layers 120, 130 and are connected to impurity regions (not shown) of the selection transistors GSL and SSL, respectively. In this case, the memory transistors WLs and the selection transistors GSL and SSL connect the common source line contact plug 122 to the bit line contact plug 132 in series. Furthermore, each of the common source line contact plug 122 and the bit line contact plug 132 may comprise conductive material. For example, each of the common source line contact plug 122 and the bit line contact plug 132 may be of at least one material selected from the group consisting of semiconductor materials (e.g., polysilicon), metal-semiconductor compounds (e.g., tungsten silicide (WSi₂)), conductive metal nitrides (e.g., titanium nitride (TiN), tantalum nitride (TaN) or tungsten nitride (WN)), and metals (e.g., titanium (Ti), tungsten (W) or tantalum (Ta)). In one example of the present embodiment, the common source line contact plug 122 and the bit line contact plug 132 each comprise a layer of tungsten.

A first barrier layer 131 may be interposed between the first interlayer insulating layer 120 and the common source line contact plug 122 and/or between the second interlayer insulating layer 130 and the bit line contact plug 132. The first barrier layer 131 may comprise a conductive metal nitride (e.g., titanium nitride, tantalum nitride or tungsten nitride).

A first capping layer 135 is provided on the second interlayer insulating layer 130. The first capping layer 135 is composed of carbon-containing material, in which carbon is present in an amount of about 2 to about 7.5 atomic percent. To this end, the first capping layer 135 may be of at least one material selected from the group consisting of silicon carbon nitride (SiCN), silicon carbon oxide (SiCO), silicon carbide (SiC), and boron carbon nitride (BCN). That is, the first capping layer 135 may be a carbide layer. In an example of this embodiment, the first capping layer 135 is a layer of silicon carbon nitride. Here, the amount of carbon in the first capping layer 135 may be that quantitatively measured using X-ray photoelectron spectroscopy (XPS), regardless of a material.

The first capping layer 135 may include a plurality of films For example, the first capping layer 135 may include a silicon carbon nitride film 135n and a silicon carbon oxide film 135o stacked or laminated on the silicon carbon nitride film 135n. In this example, the silicon carbon oxide film 135o may be one in which carbon is present in an amount of about 7 to about 10 atomic percent.

Compared with a silicon nitride layer (SiN), a carbide layer exhibits a low dielectric constant (k), relatively few Si—H bonds, and a high carbon content. In addition, a carbide layer has a lower density than a silicon nitride layer. Therefore, hydrogen-containing materials, which may diffuse in through the silicon oxide layer, can pass effectively and easily through the carbide layer. As a result, even if hydrogen or a hydrogen-containing material is produced during one of the semiconductor device fabrication processes (for example, an alloying process) or during an operation of the semiconductor device, the material will be led to the outside via the first capping layer 135, i.e., will readily dissipate from the semiconductor device.

A first silicon nitride layer 134 may be interposed between the first capping layer 135 and the second interlayer insulating layer 130. Preferably, the first silicon nitride layer 134 has a thickness of 50 angstroms or less. In this case, the first silicon nitride layer 134 may serve to improve the reliability and interfacial properties of the first capping layer 135.

A third interlayer insulating layer 140 may be provided on the first capping layer 135. Preferably, the third interlayer insulating layer 140 is of material having low permittivity. For example, the third interlayer insulating layer 140 may be a layer of silicon oxide, silicon carbon oxide, or porous silicon carbon oxide. In an example of this embodiment, the third interlayer insulating layer 140 is a TEOS oxide layer.

Furthermore, in this embodiment, a bit line 142 is disposed on the second interlayer insulating layer 130, crosses over the memory transistors WLs, and extends through the third interlayer insulating layer 140 and the first capping layer 135. The bit line 142 may comprise copper (Cu). The bit line contact plug 132 is electrically connected to the bit line 142. Practically speaking, a plurality of such bit lines 142 are provided, as crossing over the memory transistors WLs. The bit lines 142 may be formed by a damascene process.

A second barrier layer 141 may be interposed between the third interlayer insulating layer 140 and the bit line 142. In this case, the second barrier layer 141 may be a conductive metal nitride layer (e.g., a titanium nitride, tantalum nitride, or tungsten nitride layer).

A second capping layer 145 may be provided on the third interlayer insulating layer 140. In this case, the second capping layer 145 is composed of carbon-containing material, in which carbon is present in an amount of about 2 to about 7.5 atomic percent. To this end, the second capping layer 145 may be of at least one material selected from the group consisting of silicon carbon nitride (SiCN), silicon carbon oxide (SiCO), silicon carbide (SiC), and boron carbon nitride (BCN). That is, the second capping layer 145 may be a carbide layer. In an example of this embodiment, the second capping layer 145 like the first capping layer 135 is a layer of silicon carbon nitride.

Also, like the first capping layer 135, the second capping layer 145 may include a plurality of films stacked one atop the other. The films may include a silicon carbon nitride film 145n and a silicon carbon oxide film 145o on the silicon carbon nitride film 145n. Here, the silicon carbon oxide film 145o may be one containing carbon in an amount of about 7 to about 10 atomic percent.

As was mentioned above, compared with a silicon nitride layer (SiN), a carbide layer exhibits a low dielectric constant (k), relatively few Si—H bonds, and a high carbon content. In addition, a carbide layer has a lower density than a silicon nitride layer. Therefore, hydrogen-containing materials, which may diffuse in through the silicon oxide layer, can pass effectively and easily through the carbide layer. As a result, even if hydrogen or a hydrogen-containing material is produced during one of the semiconductor device fabrication processes (for example, an alloying process) or during an operation of the semiconductor device, the material will be led to the outside via the second capping layer 145, i.e., will readily dissipate from the semiconductor device.

A second silicon nitride layer 144 may be interposed between the second capping layer 145 and the third interlayer insulating layer 140. In this case, the second silicon nitride layer 144 preferably has a thickness of 50 angstroms or less. The second silicon nitride layer 144 may serve to improve reliability and interfacial properties of the second capping layer 145.

In addition, a metal capping layer 143 may be selectively provided on the bit line 142 so as to cover the metal capping layer 143 by the second capping layer 145. The metal capping layer 143 may include at least one of a cobalt-tungsten-phosphorus (CoWP) layer formed using an electroless plating method, a metal layer (e.g., a cobalt (Co), ruthenium (Ru), or manganese (Mn) layer), or a nitride layer (e.g., a manganese nitride (MnN) or copper silicon nitride (CuSiN) layer) formed using a chemical vapor deposition (CVD) method.

A fourth interlayer insulating layer 150 may be provided on the second capping layer 145. The fourth interlayer insulating layer 150 may include at least one of silicon oxide, silicon carbon oxide or porous silicon carbon oxide. Preferably, the fourth interlayer insulating layer 150 is of material having low permittivity. For example, the fourth interlayer insulating layer 150 is a TEOS oxide layer.

A via plug 152 may be disposed on the third interlayer insulating layer 140. For example, the fourth interlayer insulating layer 150 may be provided on the second capping layer 145 and a vie plug 152 may extend through the fourth interlayer insulating layer 150 and the second capping layer 145 and may be electrically connected to the bit line 142. In this case, the via plug 152 is of conductive material. For example, the via plug 152 may be of at least one material selected from the group consisting of semiconductor materials (e.g., polysilicon), metal-semiconductor compounds (e.g., tungsten silicide), conductive metal nitrides (e.g., titanium nitride, tantalum nitride, or tungsten nitride), and metals (e.g., titanium, tungsten, or tantalum). In the example of the present embodiment, the via plug 152 comprises tungsten.

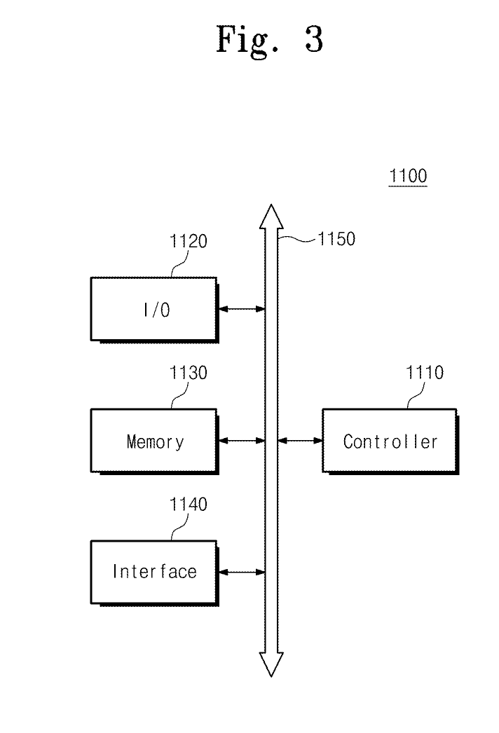

FIG. 3 illustrates an example of a memory system 1100 that may include semiconductor devices according to the inventive concept. The memory system 1100 can be applied to a personal digital assistant (PDA), a portable computer, a web tablet, a wireless phone, a mobile phone, a digital music player, a memory card or any device, for that matter, that can transmit and/or receive data in a wireless communication environment. The memory system 1100 may be embodied in such devices as solid state drive (SSD), thereby providing the devices with not only a highly integrated SSD but all of the attendant advantages of an SSD.

The memory system 1100 includes a controller 1110, an input/output device 1120 such as a keypad and a display device, a memory 1130, an interface 1140 and a bus 1150. The memory 1130 and the interface 1140 communicate with each other through the bus 1150.

The controller 1110 includes at least one microprocessor, at least one digital signal processor, at least one micro controller or the like. The memory 1130 may be used to store an instruction executed by the controller 1110. The input/output device 1120 can receive data or a signal from the outside of the system 1100 or transmit data or a signal to the outside of the system 1100 via the input/output device 1120. In this respect, the input/output device 1120 may include a keyboard, a keypad and/or a display.

The memory 1130 includes a memory device having at least one semiconductor device according to the inventive concept. The memory 1130 may also include various other kinds of memory devices such as a memory device based on semiconductor devices different than those according to the inventive concept, and a randomly accessible volatile memory device.

The interface 1140 transmits data to a communication network or receives data from a communication network.

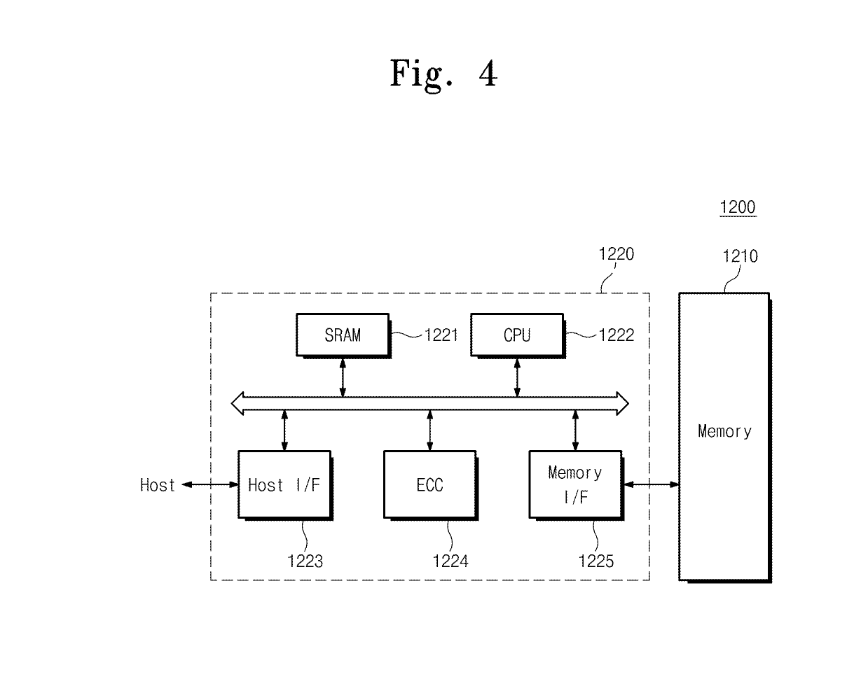

FIG. 4 illustrates an example of a memory card 1200 that may include at least one semiconductor device according to the inventive concept.

The memory card 1200 is a data storage media having a large capacity. To this end, the memory card 1200 includes a semiconductor memory device 1210 according the inventive concept, and a memory controller 1220 controlling every data exchange between a host and the semiconductor memory device 1210. The semiconductor memory device 1210 may be a multi bit device.

The memory controller 1220 includes a processing unit 1222 for controlling each exchange of data between the memory controller 1220 and the host and between the memory controller 1220 and the semiconductor memory device 1210, a static random access memory (SRAM) 1221 as an operating memory of the processing unit 1222, a host interface 1223 providing the data exchange protocol with the host to be connected to the memory card 1200, an error correction block 1224 that detects and corrects errors in data readout from the semiconductor memory device 1210, and memory interface 1225 that interfaces with the semiconductor memory device 1210. The memory card 1200 may also include a ROM (not shown) storing code for interfacing with the host.

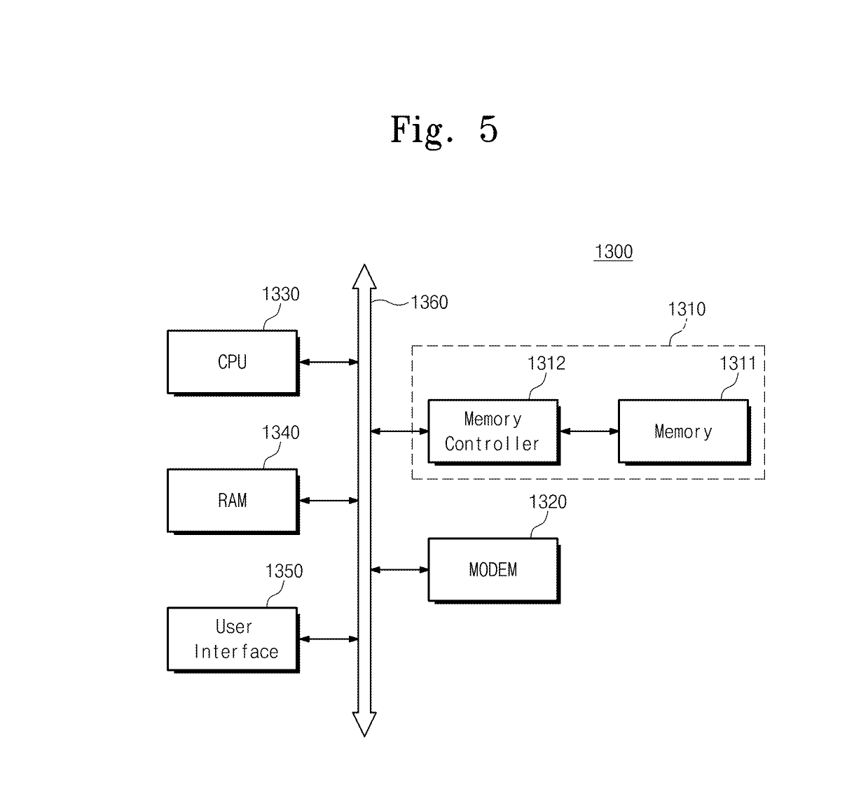

FIG. 5 illustrates an example of an information processing system 1300 including at least one semiconductor device according to the inventive concept, and which may be or be used to realize a mobile or portable device or a desktop computer.

More specifically, the information processing system 1300 has a memory system 1310 including at least one semiconductor device according to the inventive concept. The information processing system 1300 of this example also has a modem 1320, a central processing unit (CPU) 1330, a random access memory (RAM) 1340, and a user interface 1350, which are electrically connected to a system bus 1360.

The memory system 1310 may include a memory device 1311 and a memory controller 1312. In an example of this embodiment, the memory system 1310 has substantially the same configuration as the memory system shown in and described with reference to FIG. 3. Data processed by the CPU 1330 and/or input from the outside may be stored in the memory system 1310. Also, the memory system 1310 may be a portion of a solid state drive (SSD), and in this case, the information processing system 1300 will stably and reliably store a large amount of data in the memory system 1310.

Moreover, as will be readily apparent to those skilled in the art, the information processing system 1300 may also have an application chipset, a camera image sensor, a camera image signal processor (ISP), an input/output device, or the like.

Furthermore, a semiconductor device according to the inventive concept or a memory system comprising the same may be packaged in various kinds of ways. For instance, the semiconductor device or the memory system may be incorporated in a Package on Package (PoP), Ball Grid Array (BGA), Chip Scale Package (CSP), Plastic Leaded Chip Carrier (PLCC), Plastic Dual In-line Package (PDIP), Die in Waffle Pack, Die in Wafer Form, Chip On Board (COB) package, Ceramic Dual In-line Package (CERDIP), Plastic Metric Quad Flat Pack (MQFP), Thin Quad Flat Pack (TQFP), Small Outline Integrated Circuit (SOIC), Shrink Small Outline Package (SSOP), Thin Small Outline Package (TSOP), System In Package (SIP), Multi Chip Package (MCP), Wafer-level Fabricated Package (WFP), or Wafer-level Processed Stack Package (WSP). Also, any such package in which a semiconductor memory device according to the inventive concept is incorporated may additionally incorporate at least one semiconductor device (e.g., a controller and/or a logic device) that controls the semiconductor memory device.

According to aspects of the inventive concept as described above, the interconnection structure has a capping layer which is more permeable to hydrogen-containing materials, such as hydrogen (H₂) or water steam (H₂O), than a capping layer of silicon nitride. Accordingly, even if hydrogen-containing materials are produced during an operation of the semiconductor device, the materials will dissipate to the outside via the capping layer. As a result, the inventive concept obviates certain technical problems (e.g., a deterioration in retention under a high-temperature storage (HTS) test and an increase in variation or shift of threshold voltage), which may be produced by hydrogen-containing materials. Thus, the reliability and electric characteristics of a semiconductor device can be improved according to the inventive concept. For example, when a test was run on a semiconductor device according to the inventive concept and the same test was run on a semiconductor device that was similar except for its having a capping layer of silicon nitride, a change in threshold voltage was smaller, by about 30 mV, for the semiconductor device according to the inventive concept.

Finally, an embodiment of the inventive concept and examples thereof have been described above in detail. The inventive concept may, however, be embodied in many different forms and should not be construed as being limited to the embodiment described above. Rather, the embodiment and examples were described so that this disclosure is thorough and complete, and fully conveys the inventive concept to those skilled in the art. Thus, the true spirit and scope of the inventive concept is not limited by the embodiment and examples described above but by the following claims.

What is claimed is:

1. A semiconductor device, comprising:
a substrate, and at least one transistor integrated with the substrate;
an interlayer insulating layer on the substrate;
a conductive line extending within the interlayer insulating layer and electrically connected to the transistor; and
a capping layer covering the interlayer insulating layer, wherein the capping layer comprises material containing carbon present in an amount of about 2 to about 7.5 atomic percent.

2. The device of claim 1, wherein the capping layer comprises at least one material selected from the group consisting of silicon carbon nitride, silicon carbon oxide, silicon carbide, and boron carbon nitride.

3. The device of claim 1, wherein the capping layer is a composite including a film of silicon carbon nitride and a film of silicon carbon oxide on the film of silicon carbon nitride.

4. The device of claim 3, wherein the silicon carbon oxide film contains carbon in an amount of about 7 to about 10 atomic percent.

5. The device of claim 1, further comprising a silicon nitride layer below the capping layer.

6. The device of claim 5, wherein the silicon nitride layer has a thickness of 50 angstroms or less.

7. The device of claim 1, further comprising a metal capping layer extending along an upper surface of the conductive line as interposed between the conductive line and the capping layer comprising material containing carbon.

8. The device of claim 7, wherein the metal capping layer comprises one of a cobalt-tungsten-phosphorus layer, a layer of cobalt, a layer of ruthenium, a layer of manganese, and a manganese nitride layer and a copper silicon nitride layer.

9. The device of claim 1, wherein the interlayer insulating layer comprises at least one of silicon oxide and silicon carbon oxide.

10. The device of claim 1, wherein the conductive line comprises copper.

11. The device of claim 1, further comprising a contact plug extending through the interlayer insulating layer, and
wherein the conductive line is electrically connected to the transistor via the contact plug.

12. The device of claim 1, wherein the capping layer delimits an opening leading to the conductive line.

13. The device of claim 12, further comprising:
an upper interlayer insulating layer on the capping layer; and
a via plug extending through the upper interlayer insulating layer, the via plug being electrically connected to the conductive line via the opening.

14. The device of claim 1, further comprising a barrier layer interposed between the interlayer insulating layer and the conductive line.

15. A semiconductor device, comprising:
a substrate, and at least one transistor integrated with the substrate;
interlayer insulating layers on the substrate;
a conductive line extending within one of the interlayer insulating layers;
a plug of conductive material extending through another of the interlayer insulating layers and electrically connected to the conductive line; and
a capping layer interposed between said one and said another of the interlayer insulating layers and covering the conductive line, wherein the capping layer comprises material containing carbon present in an amount of about 2 to about 7.5 atomic percent.

16. The device of claim 15, wherein the capping layer comprises at least one material selected from the group consisting of silicon carbon nitride, silicon carbon oxide, silicon carbide, and boron carbon nitride.

17. The device of claim 15, wherein the capping layer is a composite including a film of silicon carbon nitride and a film of silicon carbon oxide on the film of silicon carbon nitride.

18. The device of claim 15, wherein the plug is a contact plug that contacts a bottom surface of the conductive line and electrically connects the conductive line to the transistor, and the capping layer surrounds the conductive line.

19. The device of claim 15, wherein the plug is a via plug that contacts a top surface of the conductive line, and the capping layer surrounds the via plug.

20. The device of claim 15, further comprising a metal capping layer extending along the top surface of the conductive line as interposed between the conductive line and the capping layer comprising material containing carbon.
